(19) United States
(12) Patent Application Publication
(10) Pub. No.: US 2019/0032211 A1
(43) Pub. Date: Jan. 31, 2019

(54) MONOLITHIC CERAMIC GAS DISTRIBUTION PLATE

(71) Applicant: LAM RESEARCH CORPORATION, Fremont, CA (US)

(72) Inventors: Jeremy Tucker, Mountainview, CA (US); Ramkishan Rao Lingampalli, Danville, CA (US)

(73) Assignee: LAM RESEARCH CORPORATION, Fremont, CA (US)

(21) Appl. No.: 15/662,869

(22) Filed: Jul. 28, 2017

(51) Int. Cl. C23C 16/455; H01L 21/48; H01L 21/02; C04B 35/622; H01L 21/306; B32B 18/00; C04B 35/66

(52) U.S. Cl. CPC C23C 16/45544; H01L 21/4807; H01L 21/02263; C23C 16/45561; H01J 2237/332; C04B 35/622; H01L 21/30604; B32B 18/00; C04B 35/66; C23C 16/45576

(57) ABSTRACT

A monolithic ceramic gas distribution plate for use in a process chamber wherein semiconductor substrates can be processed includes a monolithic ceramic body having an upper surface, a lower surface, and an outer cylindrical surface extending between the upper surface and the lower surface. The lower surface includes first gas outlets at uniformly spaced apart first locations and the first gas outlets are in fluid communication with first gas inlets in the upper surface by a first set of vertically extending through holes connecting the first gas inlets with the first gas outlets. The lower surface also includes second gas outlets at uniformly spaced second locations adjacent the first locations and the second gas outlets are in fluid communication with an inner plenum in the monolithic ceramic body by a second set of vertically extending through holes connecting the second gas outlets with the inner plenum. The inner plenum is in in fluid communication with a second gas inlet located in a central portion of the upper surface and the inner plenum is defined by an inner upper wall, an inner lower wall, an inner outer wall, and a set of pillars extending between the inner upper wall and the inner lower wall. Each through hole of the first set of vertically extending through holes passes through a respective one of the pillars to isolate the first and second gases.

### BACKGROUND OF THE INVENTION

Showerhead assemblies are often used in semiconductor fabrication modules to distribute process gases across the surface of a wafer or substrate during deposition, etching, or other processes. Some processes use sequential gas delivery to alternate between first and second gas supplies.

Some semiconductor fabrication methods require use of process gases which should not come into contact with each other. While there are gas delivery systems which isolate process gases until they are introduced into the reaction space in which a semiconductor substrate undergoes processing, such systems may not provide a uniform distribution of gases across the substrate. Thus, there is a need for improved gas delivery systems which can isolate process gases and introduce the gases uniformly across the substrate.

### SUMMARY

A monolithic ceramic gas distribution plate is disclosed which includes an embedded electrode. Various implementations of such a showerhead are described below and throughout this application. It is to be understood that the implementations discussed below are not to be viewed as limiting this disclosure to only the implementations shown. On the contrary, other implementations consonant with the principles and concepts outlined herein may also fall within the scope of this disclosure.

In an embodiment, a monolithic ceramic gas distribution plate for use in a process chamber wherein semiconductor substrates can be processed includes a monolithic ceramic body having an upper surface, a lower surface, and an outer cylindrical surface extending between the upper surface and the lower surface. The lower surface includes first gas outlets at uniformly spaced apart first locations and the first gas outlets are in fluid communication with first gas inlets in the upper surface by a first set of vertically extending through holes connecting the first gas inlets with the first gas outlets. The lower surface includes second gas outlets at uniformly spaced apart second locations adjacent the first locations and the second gas outlets are in fluid communication with an inner plenum in the monolithic ceramic body by a second set of vertically extending through holes connecting the second gas outlets with the inner plenum. The inner plenum is in fluid communication with a second gas inlet located in a central portion of the upper surface, the inner plenum defined by an inner upper wall, an inner lower wall, an inner outer wall, and a set of pillars extending between the inner upper wall and the inner lower wall. In this embodiment, each through hole of the first set of vertically extending through holes passes through a respective one of the pillars.

In the monolithic ceramic gas distribution plate described above, the upper surface can include an annular groove surrounding the second gas inlet.

In the monolithic ceramic gas distribution plate described above, each of the first set of vertically extending through holes can have a diameter about 3 to about 5 times smaller than a diameter of the pillar or about 6 to about 10 times the diameter of the pillar.

In the monolithic ceramic gas distribution plate described above, a planar electrode can be embedded in the monolithic ceramic body. The planar electrode can have gaps therein at locations of the first set of vertically extending through holes and at locations of the second set of vertically extending through holes, the gaps configured such that the planar electrode is not exposed to gases passing through the first and second sets of vertically extending through holes.

In the monolithic ceramic gas distribution plate described above, the pillars can be cylindrical pillars having the same diameter and/or the cylindrical pillars can be arranged in concentric rows separated by concentric rows of the second set of vertically extending through holes.

In the monolithic ceramic gas distribution plate described above, the pillars can be cylindrical pillars having the same diameter and the plenum can have a height about equal to the diameter of the pillars.

In the monolithic ceramic gas distribution plate described above, an embedded electrode can be located below the inner plenum and electrically conductive vias can extend upwardly from an outer portion of the embedded electrode at circumferentially spaced locations between an outer periphery of the monolithic ceramic body and an outermost row of the first gas outlets.

In the monolithic ceramic gas distribution plate described above, the lower surface can include an annular recess extending inwardly from an outer periphery of the monolithic ceramic body a distance less than a thickness of the monolithic ceramic body.

### BRIEF DESCRIPTION OF THE DRAWINGS

FIG. 1 depicts a cross-section of a semiconductor process chamber.

FIG. 2 depicts a perspective cutaway view of a monolithic ceramic gas distribution plate mounted in a showerhead assembly.

FIG. 3 depicts an isometric cutaway view of the showerhead assembly shown in FIG. 2.

FIG. 4 shows a perspective cutaway view of a central portion of the showerhead assembly shown in FIG. 2.

FIG. 5 depicts a top perspective view of a gas delivery assembly of the showerhead assembly shown in FIG. 2.

FIG. 6 is a bottom view of the gas delivery assembly shown in FIG. 5.

FIG. 7 depicts a perspective cutaway view of a bottom of the monolithic ceramic gas distribution plate shown in FIG. 2.

FIG. 8 depicts a cross sectional view of an outer portion of the monolithic ceramic gas distribution plate shown in FIG. 2.

FIG. 9 depicts a perspective cutaway view of an outer portion of the monolithic ceramic gas distribution plate shown in FIG. 2.

FIG. 10 depicts a perspective view of an outer portion of the monolithic ceramic gas distribution plate shown in FIG. 9 with an upper layer removed.

### DETAILED DESCRIPTION OF THE INVENTION

A gas distribution plate (also referred to herein as a “faceplate”) according to the present disclosure distributes gas and serves as an electrode in a capacitively coupled plasma (CCP) process. The gas distribution plate includes a ceramic body. In some examples, aluminum nitride (AlN), aluminum oxide (Al₂O₃), silicon nitride (Si₃N₄), yttrium oxide (Y₂O₃), zirconium oxide (ZrO₂) and composites made therefrom may be used. For example only, zirconium aluminate or yttrium aluminate may be used to provide high corrosion resistance to fluorine. The gas distribution plate includes through holes for gas distribution and an embedded electrode. In some examples, electrically conductive vias are arranged around the outer diameter of the faceplate to conduct radio frequency (RF) power to the embedded electrode.

In some examples, the electrode and vias are made of a metal with a coefficient of thermal expansion (CTE) that is closely matched to the CTE of the ceramic. In some examples, molybdenum, tungsten or another suitable metal or metal alloy may be used. In PECVD or PEALD reactors, the gas distribution plate serves as the RF powered electrode to produce a capacitively coupled plasma.

The use of ceramic allows the faceplate to be used in high temperature environments. The gas distribution plate addresses the problem of high temperature PECVD or PEALD reactors that require the gas distribution plate to serve as the powered electrode in a CCP circuit. Ceramic also makes the gas distribution plate resistant to most gas chemistries and plasmas. In some examples, the gas distribution plate is used in a CCP reactor operating at temperatures between 400° C. and 1100° C. and/or using corrosive gas chemistries. Alternatively, the gas distribution plate can be used in any PECVD CCP reactor as an electrode or in any CVD reactor as a gas distribution plate.

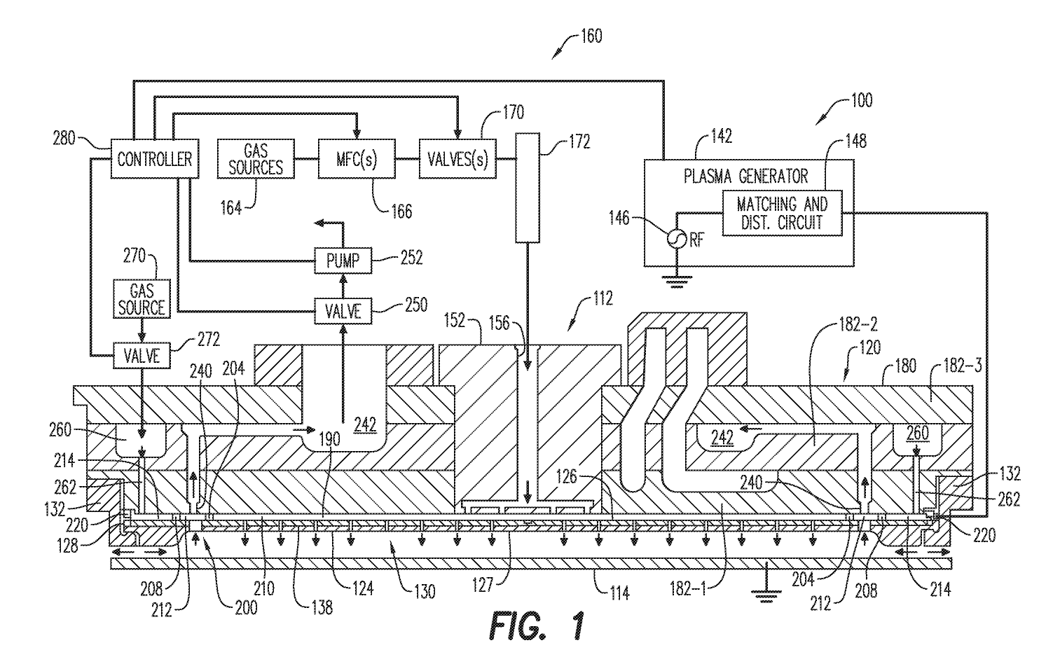

Referring now to FIG. 1, an example of a processing chamber 100 is shown. The processing chamber 100 includes a gas distribution device 112 arranged adjacent to a substrate support 114. In some examples, the processing chamber 100 may be arranged inside of another processing chamber. A pedestal may be used to lift the substrate support 114 into position to create a micro process volume. The gas distribution device 112 includes a faceplate 124 and an upper portion 120 that includes various cavities that are used to deliver process gas and purge gas and/or to remove exhaust gas as will be described further below.

In some examples, the faceplate 124 is made of a non-conducting ceramic material such as aluminum nitride. The faceplate 124 includes a ceramic body having a first surface 126, a second surface 127 (that is opposite the first surface and that faces the substrate during use), a side surface 128 and holes 130 (extending from the first surface 126 to the second surface 127). The faceplate 124 may rest on an isolator 132. In some examples, the isolator 132 may be made of Al₂O₃ or another suitable material. The faceplate 124 may include an embedded electrode 138. In some examples, the substrate support 114 is grounded or floating and the faceplate 124 is connected to a plasma generator 142. The plasma generator 142 includes an RF source 146 and a matching and distribution circuit 148.

In the example in FIG. 1, the upper portion 120 may include a center section 152 that defines a first cavity 156. In some examples, the center section 152 is made of Al₂O₃ or another suitable material. A gas delivery system 160 may be provided to supply one or more process gases, purge gases, etc. to the processing chamber 100. The gas delivery system 160 may include one or more gas sources 164 that are in fluid communication with corresponding mass flow controllers (MFCs) 166, valves 170 and a manifold 172. The manifold 172 is in fluid communication with the first cavity 156. The gas delivery system meters delivery of a gas mixture including one or more process gases to the manifold 172. The process gases may be mixed in the manifold 172 prior to delivery to the processing chamber 100. As explained below, the faceplate 124 can have two sets of gas outlets for delivering two different gas chemistries independently of each other.

The upper portion 120 also includes a radially outer section 180 arranged around the center section 152. The radially outer section 180 may include one or more layers 182-1, 182-2, . . . , and 182-N (collectively layers 182), where N is an integer greater than zero. In the example in FIG. 1, the radially outer section 180 includes N=3 layers 182 that define exhaust and gas curtain cavities, although additional or fewer layers may be used. The center section 152 and the radially outer section 180 are arranged in a spaced relationship relative to the faceplate 124 to define a second cavity 190. Process gas flows from the gas delivery system 160 through the first cavity 156 to the second cavity 190. The process gases in the second cavity 190 flows through the first plurality of holes 130 in the faceplate 124 to distribute the process gas uniformly across the substrate arranged on the substrate support 114. In some examples, the substrate support 114 is heated.

One or more annular seals may be provided to separate different portions of the second cavity. In some examples, the annular seals are nickel plated annular seals. For example, first and second annular seals 204 and 208, respectively, may be provided to define boundaries between a supply portion 210 of the second cavity 190, an exhaust portion 212 of the second cavity 190, and a gas curtain portion 214, respectively. Purge gas may be supplied by a gas source 270 and a valve 272 to the gas curtain portion 214.

In this example, the first annular seal 204 defines the boundary between the supply portion 210 and the exhaust portion 212. A third annular seal 220 (in conjunction with the second annular seal 208) may be provided to define the gas curtain portion 214 of the second cavity 190. In this example, the second annular seal 208 defines the boundary between the exhaust portion 212 and the gas curtain portion 214 of the second cavity 190. The first, second and third annular seals 204, 208, and 220, respectively, may include annular metal seals.

The radially outer section 180 further defines exhaust inlets 240 and exhaust cavities 242 that receive exhaust gas from the exhaust portion 212 of the second cavity 190. A valve 250 and a pump 252 may be used to evacuate the exhaust portion 212. The radially outer section 180 also defines a gas curtain cavity 260 and a gas curtain outlet 262 that supply purge gas to the gas curtain portion 214 of the second cavity 190. The gas source 270 and valve 272 may be used to control purge gas supplied to the gas curtain.

The third annular seal 220 may also provide an electrical connection from the plasma generator 142 to the electrode 138 embedded in the faceplate 124, although other methods for connecting the electrode 138 may be used.

A controller 280 may be used to monitor system parameters using sensors and to control the gas delivery system 160, the plasma generator 142 and other components of the process.

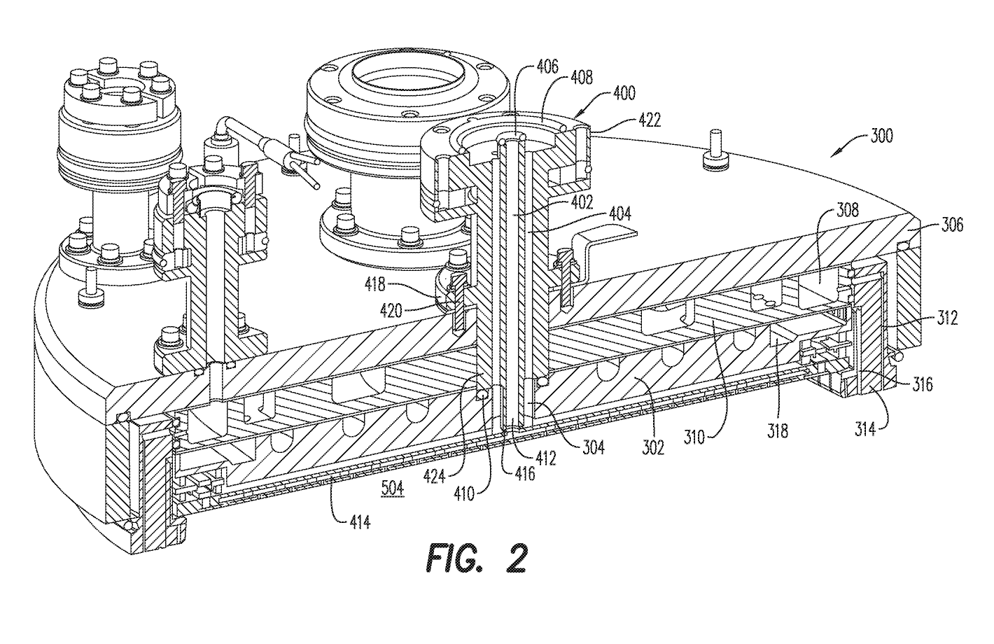

FIG. 2 shows a cross section of a showerhead module 300 wherein a gas delivery assembly 400 can supply a first gas through a centrally located inner conduit 402 and a second gas through one or more outer conduits 404 surrounding the inner conduit 402. The upper end of the gas delivery assembly 400 includes an inner seal 406 and an outer seal 408 such as metal C-rings or O-rings to isolate the first and second gases. The lower end of the gas delivery assembly 400 includes an outer seal 410 such as a metal C-ring or O-ring which seals against lower plate 302 of the showerhead module 300 such that the second gas flowing through the one or more conduits 404 passes into a central bore 304 in the lower plate. The lower end of the gas delivery assembly 400 includes a central tubular extension 412 which is sealed via an inner seal 416 such as metal C-ring or O-ring against an upper surface of faceplate 500. As explained in more detail below, the second gas flows into a first plenum (upper plenum) 414 between the lower surface of lower plate 302 and an upper surface of the faceplate 500 and the first gas flows into a second plenum (inner plenum) 502 in the faceplate 500. Thus, the first and second gases can be isolated from each other when supplied into a reaction zone 504 below the faceplate 500 during processing of a semiconductor substrate.

The gas delivery assembly 400 can be mounted onto a top plate 306 of the showerhead module 300 by means of a mounting flange 418 attached to the top plate 306 with suitable fasteners 420 such as bolts. The gas delivery assembly 400 includes an upper gas connection flange 422 and a lower stem 424 of ceramic material such as a single piece of alumina. The inner conduit 402 can have any suitable diameter such as 0.2 to 0.3 inch, preferably about 0.25 inch. The outer conduit(s) 404 can comprise six circumferentially spaced apart outer conduits 404 having the same diameter such as 0.1 to 0.2 inch, preferably about 0.15 inch. The six outer conduits 404 can be located in an annular recess 426 surrounding an upper tubular extension 428 on which inner seal 406 is supported.

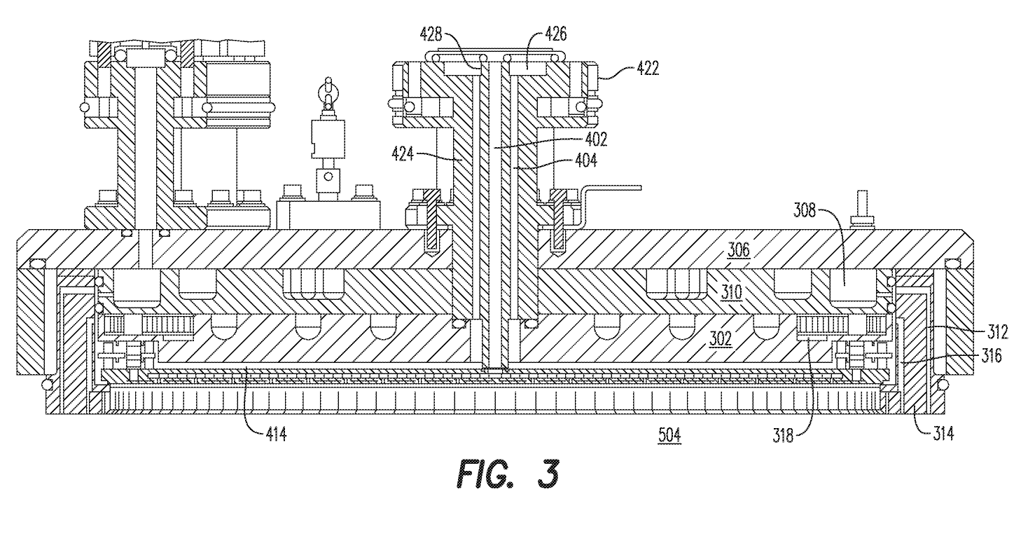

The top plate 306 can include one or more conduits connected to one or more cavities 308 in a middle plate 310 adapted to supply or evacuate gases from the reaction zone 504. For example, an outer cavity 308 can be connected to an outer ring of gas passages 312 in an isolator 314 surrounding the top plate 306 to supply a curtain of inert gas which creates a gas seal around the reaction zone 504, as shown in FIG. 3. To evacuate gas, the isolator can include an inner ring of exhaust gas passages 316 connected to cavity 318 which withdraw exhaust gas to an exhaust line.

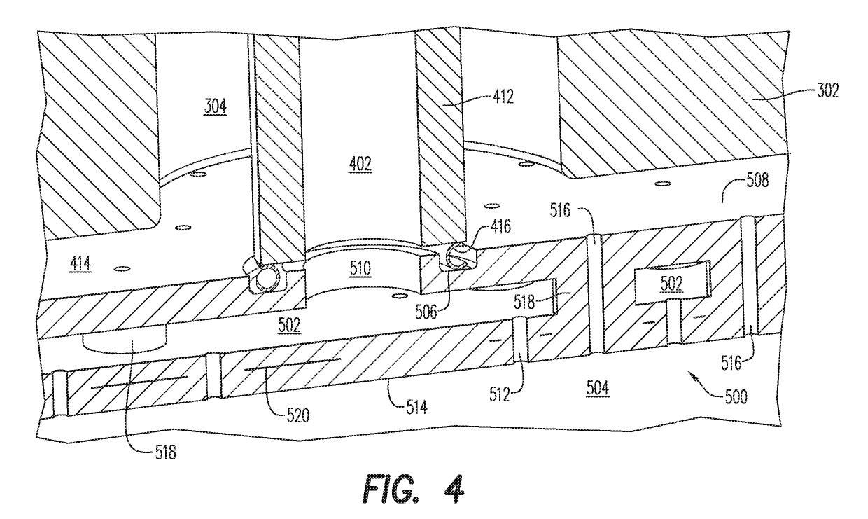

FIG. 4 shows details of a connection between the tubular extension 412 of the stem 424 of the gas delivery assembly 400 and the faceplate 500. As shown, seal 416 is located in an annular groove 506 in an upper surface 508 of the faceplate 500. A central bore 510 extending into the upper surface 508 is in fluid communication with the inner plenum 502 in the faceplate 500 and first gas passages 512 extending between the inner plenum 502 and a lower surface 514 of the faceplate allow the first gas delivered by the inner conduit 402 of the gas delivery assembly to be delivered to the reaction zone 504.

The faceplate 500 includes second gas passages 516 extending from the upper surface 508 to the lower surface 514. The second gas passages 516 allow the second gas delivered by the one or more outer conduits 404 to the upper plenum 414 above the faceplate 500 to be delivered to the reaction zone 504. To prevent the first and second gases from coming into contact before reaching the reaction zone 504, the second gas passages 516 extend through cylindrical pillars 518. The pillars 518 maximize the volume of the inner plenum 502 and increase flow uniformity of the first gas across the semiconductor substrate undergoing processing. The faceplate 500 also includes an embedded electrode 520 which couples RF energy into the reaction zone 504. In an embodiment, the upper and lower surfaces 508, 514 are planar surfaces and the embedded electrode 520 is a planar electrode oriented parallel to the planar upper and lower surfaces 508, 514.

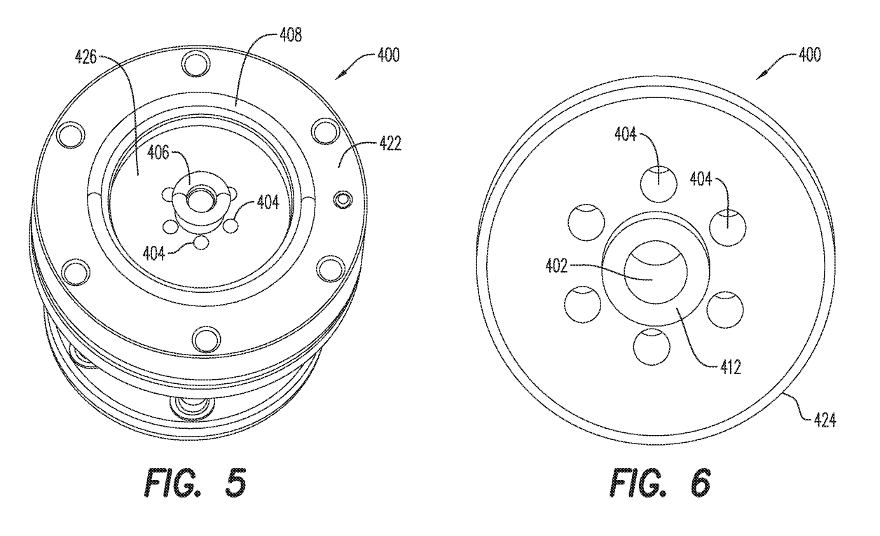

FIG. 5 shows details of the upper end of the gas delivery assembly 400. The gas delivery assembly 400 includes the gas connection flange having six bores for receipt of fasteners to attach a suitable gas supply feeding the central conduit 402 with the first gas and the six outer conduits 404 with the second gas. As shown in FIG. 6, the gas delivery assembly 400 has a lower end with outlets of the six outer conduits 404 in the lower end face of the stem 424 and the inner conduit 402 in the tubular extension 412.

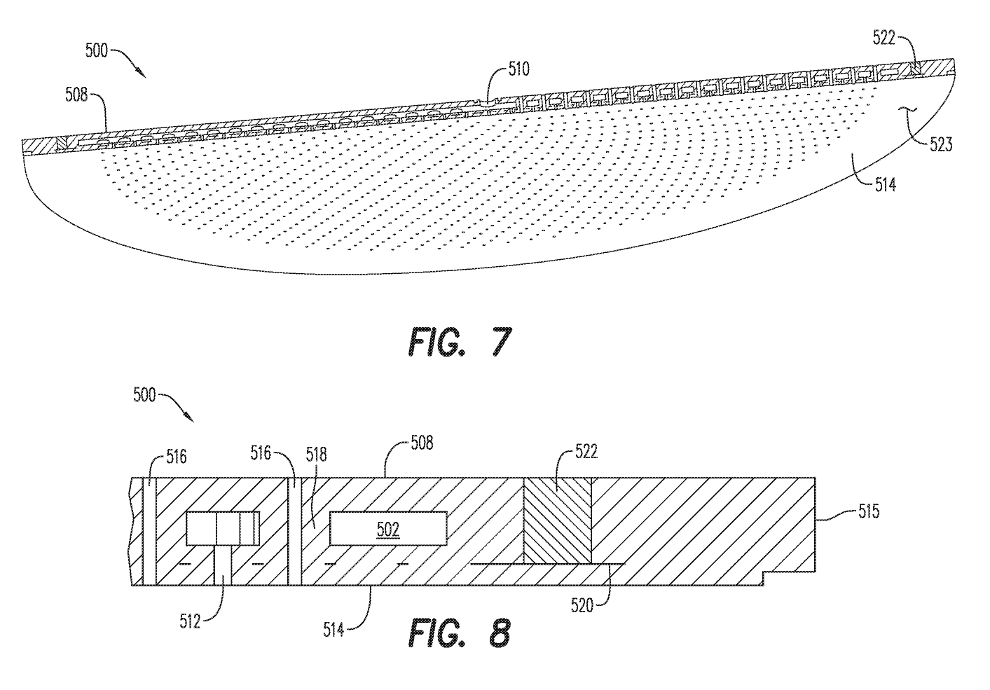

FIG. 7 is a perspective cross section of the faceplate 500 wherein it can be seen that the lower surface 514 has an even distribution of outlets of the first gas passages 512 and second gas passages 516. For example, the outlets of the gas passage 512 can be arranged in concentric rows and the outlets of the gas passages 516 can be arranged in concentric rows interposed between the rows of gas passages 512. The faceplate also includes electrically conductive vias 522 connected to the embedded electrode 520. For example, the conductive vias 522 can be located outward of an outermost row of gas passages 512, 516 and/or the conductive vias 522 can extend part way or all the way to the upper surface of the faceplate 500.

FIG. 8 is a cross section of an outer portion of the faceplate 500. As shown, a conductive via 522 extends from the upper surface 508 to the embedded electrode 520. The embedded electrode 520 is preferably a continuous plate or grid having openings at locations of the gas passages 512, 516. The conductive vias 522 can be located in an annular area 523 free of gas passages 512, 516. Alternatively, the gas passages 512, 516 can extend completely across the lower surface of the faceplate 500 and the conductive vias 522 can extend into one or more outermost rows of the gas passages 512, 516

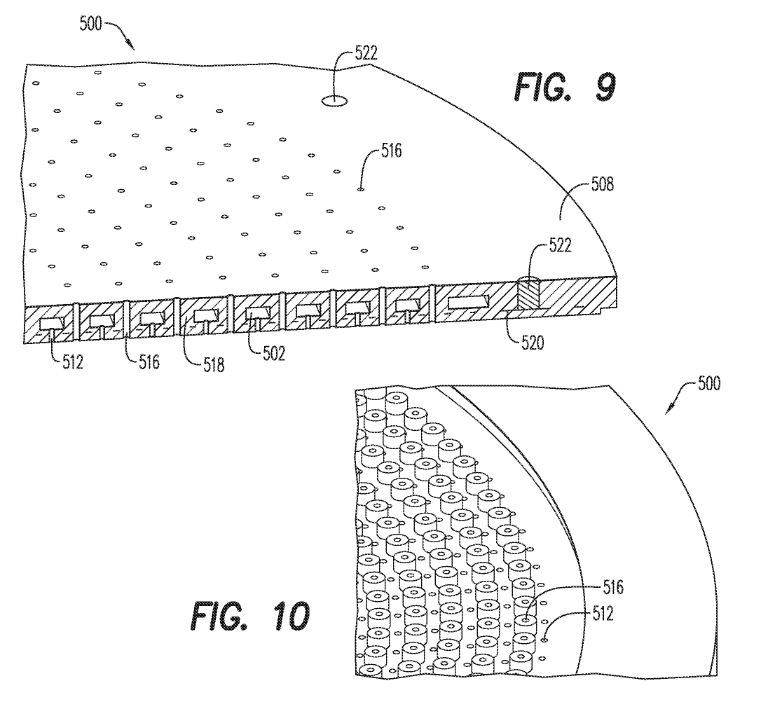

FIG. 9 is a perspective cross section of the faceplate 500 at a location passing through gas passages 516. As shown, the gas passages 512 are offset from the gas passages 516 and only inlets of the gas passages 512 can be seen in the plenum 502. The gas passages 516 can be arranged in any suitable pattern such as a series of concentric rows. Likewise, as shown in FIG. 10 wherein the top portion of the faceplate 500 is not shown to better illustrate the pillars 518, the gas passages 512 can also be arranged in a pattern of concentric rows.

In manufacturing the faceplate 500, layers of green ceramic sheets are stacked and machined as needed to provide the electrode 500, the conductive vias 522, the plenum 502, the pillars 518, the gas passages 512, 516, the central bore 510 and the O-ring groove 506. In the implementation shown above, the ceramic faceplate is a substantially annular disk with a diameter large enough to process 300 mm or 450 mm diameter semiconductor wafers.

As noted above, the ceramic faceplate 500 may include the embedded electrode 520, and the contact vias 522 which can be electrically connected to standoff posts on a contact ring which pass through the ceramic faceplate 500 via standoff blind holes in the ceramic faceplate 500 and may be in electrical contact with the embedded electrode 520 via contact patches. The embedded electrode 520 may be fused to the standoffs at the contact patches using diffusion bonding or brazing, for example. Other equivalent fusion techniques which establish an electrically-conductive joint may also be used. The standoffs on the contact ring may be manufactured separately from the contact ring and later joined to the contact ring. For example, the contact ring may include one or more hole features designed to each receive a standoff post which is then affixed to contact ring. The connection of the standoff posts to the contact ring may be permanent, e.g., fusion bonding or brazing, or reversible, e.g., threaded attachment or screws. The contact ring and the standoffs may provide an electrically-conductive pathway or pathways for an RF power source or a ground source to reach the embedded electrode 520. To provide compatible thermal expansion with a tungsten or molybdenum embedded electrode, the contact ring can be made of tungsten or molybdenum. See, for example, commonly-assigned U.S. Published Application No. 2012/0222815, the disclosure of which is hereby incorporated by reference.

The embedded electrode 520 and the monolithic ceramic gas distribution plate 500 may include a pattern of small gas distribution holes. In an implementation, approximately 1000 to 3000 gas distribution holes may pass through the embedded electrode 520 to the exposed surface of the monolithic ceramic gas distribution plate 500. For example, the gas distribution holes in the ceramic gas distribution plate 500 may be 0.03 inch in diameter, whereas the corresponding holes in the embedded electrode 520 may be 0.15 inch in diameter. Other gas distribution hole sizes may be used as well, e.g., sizes falling in the range of 0.02 inch to 0.06 inch in diameter. As a general rule, the holes in the embedded electrode 520 are at least two times larger in diameter than the corresponding gas distribution holes in the ceramic gas distribution plate 500 although the holes in the embedded electrode 520 are preferably at least 0.1 inch larger in diameter than the gas distribution holes in the ceramic gas distribution plate 500 to prevent delamination of the ceramic layers and ensure the embedded electrode 520 does not become exposed to process gas or cleaning gas.

The gas distribution holes 512, 516 may be arranged in any desired configuration, including grid arrays, polar arrays, spirals, offset spirals, hexagonal arrays, etc. The gas distribution hole arrangements may result in varying hole density across the showerhead. Different diameters of gas distribution holes may be used in different locations depending on the gas flow desired. In a preferred implementation, the gas distribution holes are all of the same nominal diameter and hole-to-hole spacing and patterned using hole circles of different diameters and with different numbers of holes.

The gas distribution holes 512, 516 may have a uniform diameter or vary in diameter through the thickness of the ceramic gas distribution plate 500. For example, the gas distribution holes may be a first diameter on the surface of the ceramic gas distribution plate 500 facing the lower plate 302 and may be a second diameter when the gas distribution holes exit the exposed lower surface 514 facing the substrate to be processed. The first diameter may be larger than the second diameter. Regardless of the potential for varying gas distribution hole sizes, the holes in embedded electrode 520 may be sized relative to the diameter of the gas distribution holes in the ceramic gas distribution plate 500 as measured in the same plane as the embedded electrode 520.

The ceramic faceplate 500 may be manufactured from Aluminum Oxide (Al₂O₃) or Aluminum Nitride (AlN), Silicon Nitride (Si₃N₄), or Silicon Carbide. Other materials exhibiting strong resistance to attack by fluorine and good dimensional stability at high temperature, i.e., 500-600° C., may be used as well. The particular ceramic used may need to be selected to avoid chemical interactions with the process gases used in particular semiconductor processing applications. Boron Nitride (BN) and Aluminum Oxynitride (AlON) are further examples of ceramics which may be used in this application, although these materials may be challenging to implement due to manufacturing issues.

The embedded electrode 520, as well as elements of the conductive path to the embedded electrode 520, may, for example, be manufactured from tungsten or molybdenum. Other electrically-conductive materials with high temperature resistance and with coefficients of thermal expansion similar to that of the ceramic faceplate material may be used. Portions of the conductive path to the embedded electrode 520 which may not be encapsulated within the ceramic gas distribution plate 500 may be coated with a protective coating, such as nickel plating, which may prevent or reduce damage to the conductive pathways due to process gas exposure. Other protective coatings may be used as well, such as coatings of noble metals which retain their resistance to corrosion and oxidation at elevated temperatures, e.g., gold, platinum, palladium, or iridium.

The contact ring may be manufactured from tungsten or molybdenum as well; the contact ring may typically be manufactured from a material which is bond-compatible with the embedded electrode and which has similar thermal expansion characteristics.

The monolithic ceramic gas distribution plate 500 can be mounted in the chamber to provide an upper plenum (plenum 1) which delivers gas through longer gas passages 516 than the gas delivered through the shorter gas passages 512 from the inner plenum 502 (plenum 2). The faceplate 500 can be made by tape casting laminate manufacturing techniques and a majority of the structural features such as posts (pillars 518) and channel 506 can be machined in the green state. The upper plenum (plenum 1) can be free of baffles to allow gas delivered from the outer gas conduits 404 to flow unrestricted in the upper plenum 414 (plenum 1) and exit through longer gas passages 516. Similarly, the gas delivered by central conduit 402 can flow freely through the inner plenum 502 (plenum 2) and exit through shorter gas passages 512. The longer gas passages 516 can be greater in number than the shorter gas passages 512 to compensate for the longer higher pressure drop due to the longer gas passages 516. For example, the ceramic gas distribution plate 500 can have about 910-930 shorter gas passages 512 and about 960-980 longer gas passages 516. The longer gas passages 516 can be arranged on concentric circular rows such as 15-20 rows of holes. Similarly, the shorter gas passages 512 can be arranged on concentric circular rows such as 15-20 rows of holes alternating with the rows of longer gas passages 516. Preferably, the longer gas passages 516 are arranged in the same number of rows as the shorter gas passages 512 and the radial spacing between the holes is the same for the longer and shorter gas passages 512, 516. The inner plenum 502 preferably has a small height of about 0.1 inch or less with a total volume of about 200 cc or less. In an embodiment, the gas passages 512, 516 extend close to the outer periphery of the ceramic gas distribution plate 500 and six conductive vias 522 for supplying power to the embedded electrode 520 can be located at positions which extend into one or more outermost row of gas passages 512, 516.

In ALD processing, different gas chemistries are sequentially supplied to carry out cycles of a dose step followed by a conversion step. When using the ceramic gas distribution plate 500 for ALD, the dose gas can be supplied to plenum 1 (upper plenum 414) which is in fluid communication with a higher number of longer gas passages 516 and the conversion gas can be supplied to plenum 2 (inner plenum 502) which is in fluid communication with a smaller number of shorter gas passages 512.

Although several implementations of this invention have been described in detail herein with reference to the accompanying drawings, it is to be understood that the invention is not limited to these precise implementations, and that various changes and modifications may be effected therein by one skilled in the art without departing from the scope of spirit of the invention as defined in the appended claims.

What is claimed is:

1. A monolithic ceramic gas distribution plate for use in a chemical deposition apparatus wherein semiconductor substrates can be processed, the gas distribution plate comprising:
a monolithic ceramic body having an upper surface, a lower surface, and an outer cylindrical surface extending between the upper surface and the lower surface;
first gas outlets in the lower surface at uniformly spaced apart first locations, the first gas outlets in fluid communication with first gas inlets in the upper surface by a first set of vertically extending through holes connecting the first gas inlets with the first gas outlets;
second gas outlets in the lower surface at uniformly spaced second locations adjacent the first locations, the second gas outlets in fluid communication with an inner plenum in the monolithic ceramic body by a second set of vertically extending through holes connecting the second gas outlets with the inner plenum, the inner plenum in fluid communication with a second gas inlet located in a central portion of the upper surface;
the inner plenum defined by an inner upper wall, an inner lower wall, an inner outer wall, and a set of pillars extending between the inner upper wall and the inner lower wall; and
each through hole of the first set of vertically extending through holes passing through a respective one of the pillars.

2. The monolithic ceramic gas distribution plate of claim 1, further comprising an annular groove in the upper surface, the annular groove surrounding the second gas inlet.

3. The monolithic ceramic gas distribution plate of claim 1, wherein the pillars are cylindrical pillars having the same diameter and each of the first set of vertically extending through holes has a diameter about 3 to about 5 times smaller than the diameter of the pillar or about 6 to about 10 times the diameter of the pillar.

4. The monolithic ceramic gas distribution plate of claim 1, further comprising a planar electrode embedded in the monolithic ceramic body, the planar electrode having gaps therein at locations of the first set of vertically extending through holes and at locations of the second set of vertically extending through holes such that the planar electrode is not exposed to gases passing through the first and second sets of vertically extending through holes.

5. The monolithic ceramic gas distribution plate of claim 1, wherein the pillars are cylindrical pillars having the same diameter, the pillars arranged in concentric rows separated by concentric rows of the second set of vertically extending through holes.

6. The monolithic ceramic gas distribution plate of claim 1, wherein the upper and lower surfaces are planar surfaces and the pillars are cylindrical pillars having the same diameter, the inner plenum having a height about equal to the diameter of the pillars.

7. The monolithic ceramic gas distribution plate of claim 1, further comprising an embedded electrode below the inner plenum and electrically conductive vias extending upwardly from the embedded electrode at circumferentially spaced locations between an outer periphery of the monolithic ceramic body and an outermost row of the first gas outlets.

8. The monolithic ceramic gas distribution plate of claim 1, further comprising an annular recess surrounding the lower surface, the annular recess extending inwardly from an outer periphery of the monolithic ceramic body a distance less than a thickness of the monolithic ceramic body.

9. A showerhead module comprising the gas distribution plate of claim 1 and a gas delivery assembly, the showerhead module including a top plate supporting the gas delivery assembly such that a stem of the gas delivery assembly extends through a central bore in a lower plate of the showerhead module, the gas distribution assembly including a centrally located inner gas conduit in fluid communication with the inner plenum and at least one outer gas conduit in fluid communication with an upper plenum between a lower surface of the lower plate and the upper surface of the monolithic ceramic body.

10. The showerhead module of claim 9, wherein a lower end of the stem of the gas delivery assembly includes a tubular extension which extends below the lower surface of the lower plate and an annular seal is located between an end of the tubular extension and the upper surface of the monolithic ceramic body to isolate gas delivered through the central gas conduit from gas delivered through the at least one outer gas conduit.

11. The showerhead module of claim 10, wherein the lower plate includes a central bore spaced outwardly from the tubular extension by an annular gap in fluid communication with the upper plenum, and an annular seal in an annular groove in an upper surface of the lower plate seals against the lower end of the stem.

12. The showerhead module of claim 9, wherein the gas delivery assembly includes an outwardly extending mounting flange attached to the top plate of the showerhead module, an upper gas connection flange at an upper end of the stem, the gas connection flange including an annular recess in an upper surface thereof and the at least one outer gas conduit comprising six circumferentially spaced apart outer gas conduits with inlets thereof in the annular recess.

13. A method for manufacturing the gas distribution plate of claim 1, comprising machining the second set of through holes in a first ceramic green sheet; printing the embedded electrode on an upper surface of the first ceramic green sheet; overlaying the first ceramic green sheet with a second ceramic green sheet; machining the inner plenum and pillars in the second ceramic green sheet; overlaying the second ceramic green sheet with a third ceramic green sheet; machining the first set of through holes in the first, second and third green ceramic sheets such that each of the first set of through holes passes through a respective one of the pillars; and sintering the green ceramic sheets to form the monolithic ceramic gas distribution plate.

14. The method of claim 13, wherein the embedded electrode is made of a material having a coefficient of thermal expansion that matches a coefficient of thermal expansion of the monolithic ceramic body.

15. The method of claim 13, wherein the embedded electrode is made of molybdenum and/or tungsten.

16. The method of claim 13, wherein the ceramic green sheets are made of a material selected from a group consisting of aluminum nitride (AlN), aluminum oxide (Al₂O₃), silicon nitride (Si₃N₄), yttrium oxide (Y₂O₃), zirconium oxide (ZrO₂) and composites thereof.

17. The method of claim 13, further comprising machining the gas inlet and the annular groove in an upper surface of the third ceramic green sheet.

18. The method of claim 13, further comprising machining vias in the third ceramic green sheet at circumferentially spaced locations between an outer periphery of the third ceramic green sheet and an outermost row of the first gas outlets, and at least partially filling each of the vias with an electrically conductive material which provides an electrical connection to the embedded electrode.

19. The method of claim 18, wherein the vias are partially filled such that recesses extend into the upper surface of the monolithic ceramic body.

20. The method of claim 13, further comprising forming an annular recess surrounding the lower surface such that the annular recess extends inwardly from an outer periphery of the monolithic ceramic body a distance less than a thickness of the monolithic ceramic body and machining a gas inlet in a central portion of the third ceramic green sheet such that the gas inlet is in fluid communication with the inner plenum.
